(19) United States
(12) Patent Application Publication
(10) Pub. No.: US 2026/0032898 A1
(43) Pub. Date: Jan. 29, 2026

(54) MOSFET GATE STACK STRUCTURES WITH REDUCED HEIGHTS AND EFFECTIVE WORK FUNCTION ADJUSTMENT

(71) Applicant: Micron Technology, Inc., Boise, ID (US)

(72) Inventors: Huajie Chen, Boise, ID (US); Carlo Mendoza Orofeo, Singapore (SG); Brenda D. Kraus, Boise, ID (US); Karine Paulette Pierrette Florent, Boise, ID (US); Dan Mocuta, Boise, ID (US); Durai Vishak Nirmal Ramaswamy, Boise, ID (US); Shivani Srivastava, Boise, ID (US)

(21) Appl. No.: 19/278,432

(22) Filed: Jul. 23, 2025

Related U.S. Application Data
(60) Provisional application No. 63/674,958, filed on Jul. 24, 2024.

(51) Int. Cl. H10B 12/00

(52) U.S. Cl. CPC H10B 12/50

(57) ABSTRACT

Metal-oxide-semiconductor field-effect transistor (MOSFET) gate stack structures with reduced heights and effective work function adjustment are disclosed herein. The MOSFET includes one or more transistors, each including a high-k metal gate (HKMG) stack comprising a high-K dielectric layer, a stack of gate work function metal layers disposed on the high-K dielectric layer, a capping layer disposed on the stack of the gate work function metal layers, and a tungsten silicide (WSix) layer disposed over and directly connected to the capping layer. The capping layer can have a thickness of 5 nm or less.

### CROSS-REFERENCE TO RELATED APPLICATION(S)

The present application claims priority to U.S. Provisional Patent Application No. 63/674,958, filed Jul. 24, 2024, the disclosure of which is incorporated herein by reference in its entirety.

### TECHNICAL FIELD

The present disclosure generally relates to semiconductor devices. For example, several embodiments of the present disclosure discussed in detail below relate to metal-oxide-semiconductor field-effect transistor (MOSFET) gate stack structures (e.g., high-k metal gate (HKMG) stack structures) that each employ a capping layer that (a) can be used in lieu of a thick polysilicon layer to achieve a stack height reduction and/or (b) can be used to adjust or optimize MOSFET gate effective work functions.

### BACKGROUND

In modern semiconductor devices, minimizing parasitic capacitance is essential for enhancing performance and reducing power consumption. A significant component of parasitic capacitance is the overlap capacitance between the gate and the source/drain regions, referred to as gate-to-source/drain capacitance (Cₒᵥ). Thinner polysilicon gates reduce the overlap capacitance through the reduction of capacitance between gate and source/drain contacts. This polysilicon gate thickness reduction contributes to a decrease in overall parasitic capacitance, supporting the ongoing trend towards smaller and more efficient semiconductor devices.

Additionally, many modern memory device designs always involve co-integration of periphery circuits (including MOSFET devices) with memory arrays. This co-integration is crucial for performance, efficiency, and scalability of memory technologies, such as DRAM, NAND flash, and high-bandwidth memory (HBM). For example, the co-integration of periphery circuits and memory arrays can reduce the distance between memory arrays and their controlling circuits, leading to faster data access times and higher bandwidth. In addition, the compact nature of co-integrated memory device packaging allows for more memory capacity within a smaller footprint, which is important for mobile devices and other space-constrained applications. The co-integration of periphery circuits with memory arrays, however, may cause height variance therebetween, causing manufacturing complexity and other challenges.

### BRIEF DESCRIPTION OF THE DRAWINGS

Many aspects of the present disclosure can be better understood with reference to the following drawings. The components in the drawings are not necessarily to scale. Instead, emphasis is placed on illustrating clearly the principles of the present disclosure. The drawings should not be taken to limit the disclosure to the specific embodiments depicted, but are for explanation and understanding only.

FIG. 1 is a partially schematic side view of a memory device having a periphery stack of a first height and a memory array of a second height.

FIG. 2 is a partially schematic block diagram of a computing device including a memory device configured in accordance with various embodiments of the present disclosure.

FIG. 3 is a partially schematic, cross-sectional side view of a memory device configured in accordance with various embodiments of the present disclosure.

FIGS. 4A and 4B are partially schematic side views of capping layers formed above titanium nitride layers of transistor gate stacks configured in accordance with various embodiments of the present disclosure.

FIGS. 4C and 4D are partially schematic side views of capping layers formed above titanium silicon nitride layers of transistor gate stacks configured in accordance with various embodiments of the present disclosure.

FIGS. 4E and 4F are partially schematic side views of capping layers formed above titanium nitride layers of transistor gate stacks configured in accordance with various embodiments of the present disclosure.

FIG. 5 is a partially schematic, cross-sectional side view a transistor gate stack structure configured in accordance with various embodiments of the present disclosure.

FIGS. 6A, 6B, and 6C are partially schematic, cross-sectional side views of MOSFET devices having fin field-effect transistor (FinFET), nanosheet gate-all-around (GAA), and nanowire GAA structures, respectively, configured in accordance with various embodiments of the present disclosure.

FIG. 7 is a flowchart illustrating a method for fabricating at least part of a gate stack of a MOSFET device in accordance with various embodiments of the present disclosure.

FIG. 8 is a flowchart illustrating a method for fabricating a MOSFET device gate stack in accordance with various embodiments of the present disclosure.

FIG. 9 is a partially schematic block diagram of a system that includes a semiconductor memory device configured in accordance with various embodiments of the present disclosure.

### DETAILED DESCRIPTION

Advanced semiconductor technology requests for superior device performance and lower power consumption. A critical factor in achieving these objectives is the reduction of parasitic capacitance within semiconductor components. Parasitic capacitance existing on a transistor device can impede the device's response time and increase energy usage, thus being imperative to be minimized for optimal transistor device functionalities. A primary source of parasitic capacitance in semiconductor devices is the gate-to-source/drain capacitance (also called overlap capacitance), often abbreviated as Cₒᵥ. This specific overlap capacitance arises from the overlap between the gate electrode and the source/drain regions of a transistor. The magnitude of this overlap capacitance is a determinant of the device's performance, as it can significantly affect the speed and power efficiency of the semiconductor device.

The utilization of thinner polysilicon gates is a viable strategy to reduce the overall gate capacitance, which in turn has a beneficial effect on the overlap capacitance. The rationale behind this approach is that a reduction in the thickness of the polysilicon layer leads to a reduced capacitance between the gate and the adjacent source/drain contacts in a transistor. Consequently, the elimination of polysilicon gate diminishes the overlap capacitance, thereby enhancing the device's performance by allowing for faster switching speeds and lower power dissipation.

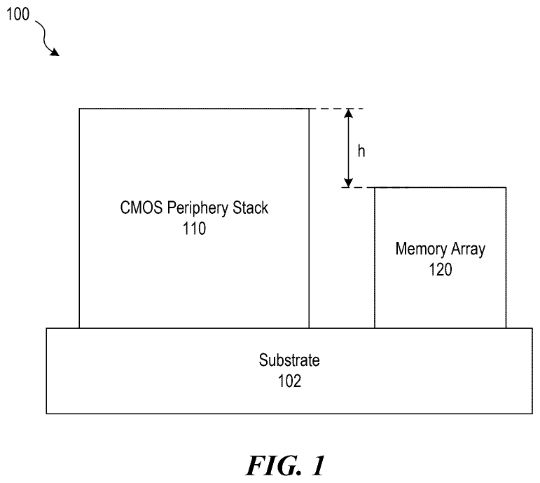

In addition, modern memory devices are increasingly integrated into compact and efficient systems in which both periphery circuits and memory arrays are included within the same packaging or even on the same dies. Such integration aims to improve performance, reduce latency, and increase the speed of data transfer between the periphery circuits and memory components in the memory devices. For example, FIG. 1 is a partially schematic side view of a memory device 100 having a complementary metal-oxide-semiconductor (CMOS) periphery stack 110 and a memory array 120. In the illustrated example, the CMOS periphery stack 110 and the memory array 120 are co-integrated on a substrate 102. The substrate 102 can be or include silicon. The CMOS periphery stack 110 and the memory array 120 can be disposed at various locations above a frontside surface of the substrate 102. As a specific example, the memory array 120 and the CMOS periphery stack 110 can be arranged on a same silicon die, such as with the memory array 120 occupying a large central area of the die and periphery circuits of the CMOS periphery stack 110 distributed about or proximate the edges of the die. The memory array 120 can include a plurality of memory cells where data can be stored, and the CMOS periphery stack 110 can include one or more periphery circuits (e.g., decoders, sense amplifiers, control logic, CMOS transistors) that handle access to the memory cells of the memory array 120, refresh operations of the memory cells, and/or communication with external circuits. Memory cells of the memory array 120 can be arranged in a grid of rows and columns, and CMOS periphery circuits of the CMOS periphery stack 110 can be built or arranged adjacent to the memory cells. In some examples, the memory device 100 can be or include a DRAM device and/or a NAND flash device.

As shown in FIG. 1, a height variance (shown by arrow h) between the memory array 120 and the CMOS periphery stack 110 may exist in the memory device 100. Particularly, the CMOS periphery stack 110 may have a first height that is greater than a second height of the memory array 120. Thus, the CMOS periphery stack 110 may have a top surface that is positioned higher than a top surface of the memory array 120. The height variance can be caused by device structure and fabrication processes involved in the CMOS periphery stack 110 and the memory array 120. Such a height variance can lead to planarity issues during fabrication processes. For example, planarity can be crucial for lithography steps where a uniform height across a surface is needed. Non-planar surfaces within the memory device 100 can result in defects and yield issues due to improper patterning. In addition, a height variance can introduce mechanical stresses and strains within the memory device 100. This is because different materials used in the memory array 120 and the CMOS periphery stack 110 might expand or contract differently under temperature changes. Such stresses/strains can lead to cracking, delamination, or other forms of physical degradation, which can negatively impact the reliability of the memory device 100. Further, a height variance among components of the memory device 100 can complicate integration of the memory device 100 with other components and its packaging. This can lead to challenges in achieving a compact and efficient design. In advanced memory technologies (e.g., 3D NAND flash) in which multiple layers of memory cells are stacked vertically, a height variance can add complexity to the stacking and alignment processes of the layers, further challenging memory device fabrication and yield.

To address the above described concerns on overlap capacitance and leveling between memory array and periphery circuits, the present disclosure is directed to advanced fabrication techniques and novel transistor design strategies. For example, as discussed in greater detail below, several embodiments of the present disclosure are directed to reduction of gate stack heights of CMOS transistors (e.g., in CMOS periphery stacks, such as in the CMOS periphery stack 110 described above) by eliminating a polysilicon layer and/or associated barrier metal layers from the gate stacks. In one example, the elimination of thick polysilicon and/or associated barrier metal layers in accordance with the present disclosure achieve more than a 10 nm CMOS transistor gate stack height reduction, which is expected to reduce the overlap capacitance and a height variance between a CMOS periphery stack and a corresponding memory array of a memory device. In some embodiments of the present disclosure, a gate stack can include a thin capping layer between a stack of metal layers and a tungsten silicide layer in the gate, such as to better control effective work function (eWF) levels of the gate stack. This thin capping layer can be made of polycrystalline silicon, amorphous silicon, titanium silicon nitride, or a combination thereof, and can have various thicknesses to provide gate stack effective work functions at various desired levels. Further, the thin capping layer can be adopted into both NMOS and PMOS regions of the CMOS transistor for advanced memory device packaging.

As a result, the present disclosure is expected to achieve a reduction of gate stack heights and/or greater uniformity between periphery stacks and memory arrays. In turn, the present disclosure is expected to achieve greater planarity between periphery circuits and memory arrays, which is expected to reduce, mitigate, or eliminate the various issues (e.g., the defects and yield issues due to improper patterning; the mechanical stresses/strains introduced within the memory devices that can lead to cracking, delamination, or other forms of physical degradation; and/or the fabrication or integration challenges) discussed above.

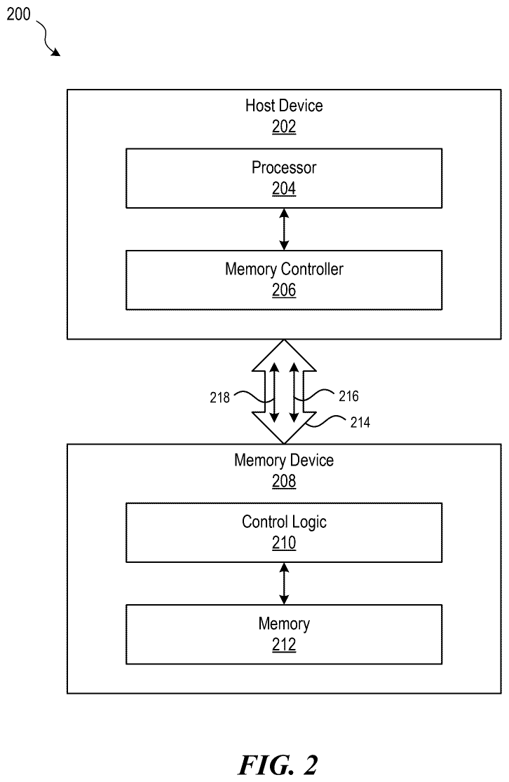

FIG. 2 is a partially schematic block diagram of a computing device 200 including a memory device 208 configured in accordance with various embodiments of the present disclosure. As shown, the computing device 200 includes (a) a host device 202 having at least one processor 204 and at least one memory controller 206, and (b) a memory device 208 including control logic 210 and memory 212. In some examples, the memory controller 206 may be an aspect of, and may reside on or within, the processor 204 (or vice versa). The computing device 200 further includes an interconnect 214. The computing device 200 can be or include any type of computing device, computing equipment, computing system, or electronic device. For example, the computing device 200 can be or include hand-held devices (e.g., mobile phones, tablets, digital readers, digital audio players), computers, vehicles, or appliances. Components of the computing device 200 may be housed in a single unit or distributed over multiple, interconnected units (e.g., through wired or wireless interconnects). In some embodiments, the host device 202 and the memory device 208 are discrete components mounted to and electrically coupled through an interposer (e.g., implementing a portion of the interconnect 214).

As shown, the host device 202 and the memory device 208 are coupled with one another through the interconnect 214. The processor 204 executes instructions that cause the memory controller 206 of the host device 202 to send, via the interconnect 214, signals to the memory device 208 that control operations at the memory device 208. The memory device 208 can similarly communicate data to the host device 202 via the interconnect 214. The interconnect 214 can include one or more command/address (CA) buses 216 or one or more data (DQ) buses 218. The CA buses 216 can communicate control signaling indicative of commands to be performed at select locations (e.g., addresses) of the memory device 208. The DQ buses 218 can communicate data between the host device 202 and the memory device 208. For example, the DQ buses 218 can be used to communicate data from the host device 202 to the memory device 208 to store the data in the memory device 208 in accordance with a write request. As another example, the DQ buses 218 can be used to communicate data retrieved from memory device 208 to the host device 202 in accordance with a read request. The CA buses 216 can be realized using a group of wires, and the DQ buses 218 can encompass a different group of wires of the interconnect 214. In some embodiments, the interconnect 214 can include a front-side bus, a memory bus, an internal bus, a peripheral control interface (PCI) bus, etc.

The processor 204 can read data from and write data to the memory device 208 through the memory controller 206. The processor 204 may include a host processor, a central processing unit (CPU), a graphics processing unit (GPU), an artificial intelligence (AI) processor (e.g., a neural-network accelerator), or other hardware processor or processing unit of the computing device 200.

In some examples, the memory device 208 can be integrated with the host device 202 or be separate from the computing device 200. The memory device 208 can include any memory 212, such as integrated circuit memory, dynamic memory, random-access memory (e.g., dynamic random-access memory (DRAM), static random-access memory (SRAM)), high-bandwidth memory (HBM), or NAND flash memory to name just a few. The memory device 208 can include memory 212 of a single type or memory 212 of multiple types. In general, the memory device 208 can be implemented as any addressable memory having identifiable locations of physical storage. The memory device 208 can include memory-side control logic 210 that executes commands from the memory controller 206. For example, the memory-side control logic 210 can decode signals received from the memory controller 206 and perform operations at the memory 212.

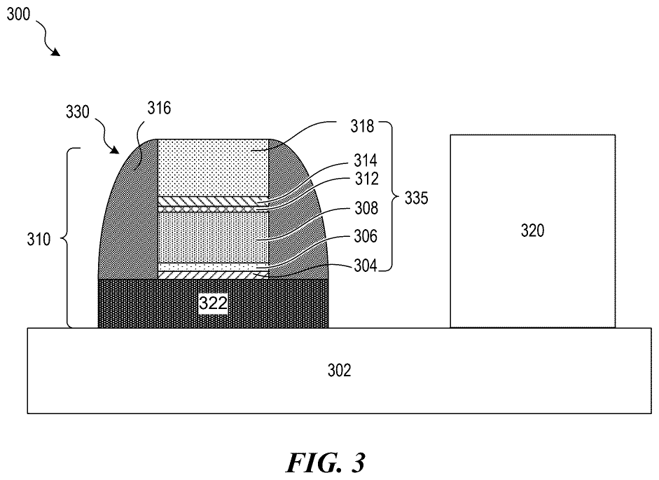

As a specific example, the memory device 208 can include an HBM device. For example, the memory device 208 can include (a) an interface die implementing at least a portion of the memory-side control logic 210 and (b) one or more memory 212 (e.g., memory dies, DRAM memory dies) stacked on the interface die. The memory-side control logic 210 can receive commands from the memory controller 206 through the interconnect 214 and can communicate corresponding signaling to execute the commands at the memory 212. The interconnect 214 can similarly be implemented in accordance with the HBM device. For example, the interconnect 214 can include a number (e.g., 32) of channels that are further divided into two pseudo channels per channel. Each channel can be coupled to a CA bus, and each pseudo channel can transmit or receive data through a respective DQ bus. Thus, the interconnect 214 can include twice as many DQ buses 218 (e.g., 64 DQ buses) as CA buses 216 (e.g., 32 CA buses). Further details of memory devices (e.g., memory devices generally similar to the memory device 208) will be described in greater detail below with reference to FIGS. 3-9.

FIG. 3 is a partially schematic, cross-sectional side view of a memory device 300 configured in accordance with various embodiments of the present disclosure. The memory device 300 includes a periphery stack 310 (e.g., similar to the CMOS periphery stack 110 of FIG. 1) and a memory array 320 (e.g., similar to the memory array 120 of FIG. 1) disposed on a substrate 302. The periphery stack 310 includes one or more metal-oxide semiconductor field-effect transistors (MOSFETs) 330.

In some embodiments, the MOSFETs 330 can include planar transistor devices (e.g., fabricated using gate-first or other suitable processes). For example, FIG. 3 shows a cross-sectional side view of the memory device 300 taken along a channel of one of the MOSFETs 330. As shown, the MOSFET 330 includes a substrate 322, a gate stack 335 positioned over the substrate 322, and a spacer 316 disposed about the gate stack 335. The gate stack 335 of the MOSFET 330 can be a high-K metal gate (HKMG) stack that includes several layers. For example, the gate stack 335 includes a gate oxide/interfacial layer 304, a high-k dielectric layer 306, and a stack of gate metal layers 308 (also referred to herein as gate work function metal layers). The gate stack 335 additionally includes a capping layer 312 disposed above and directly connected to the stack of gate metal layers 308, a tungsten silicide (WSix) layer 314 directly deposited on the capping layer 312, and a tungsten layer 318 disposed over the WSix layer 314. As discussed in greater detail below, the gate stack 335 of the MOSFET 330 shown in FIG. 3 can have shorter height in comparison to the gate stacks of traditional MOSFETs. The shorter height of the MOSFET 330 can be at least partially achieved by omitting a thick polysilicon layer that is typically included in the gate stacks of traditional MOSFETs.

The substrate 322 of the MOSFET 330 includes a channel (not shown) between a source region (not shown) and a drain region (not shown). The substrate 322 can be made of silicon or another suitable material. When a gate voltage is applied to the MOSFET 330, the gate voltage induces an inversion layer in the substrate 322, allowing current to flow between the source and drain regions. The channel's conductivity is modulated by the gate voltage, which controls the on and off states of the MOSFET 330. In the illustrated embodiment, the interfacial layer 304 can be disposed on the channel of the substrate 322 and beneath the high-K dielectric layer 306 to improve the interface quality and to reduce gate leakage. The interfacial layer 304 can be a thermally grown silicon dioxide, a chemical oxide, or a chemically deposited oxide. The high-K dielectric layer 306 deposited on the interfacial layer 304 further reduces gate leakage while maintaining a strong capacitive coupling between gate electrode and the channel. Dielectric materials such as hafnium oxide can be used to form the high-K dielectric layer 306.

The stack of gate metal layers 308 positioned over the high-K dielectric layer 306 can be a combination of materials configured to tune effective gate work function and other characteristics of the MOSFET 330. The stack of gate metal layers 308 can depend on whether the MOSFET 330 is an NMOS or PMOS transistor. For example, in the event the MOSFET 330 is an NMOS transistor, the stack of gate metal layers 308 can include a first titanium nitride layer and a lanthanum layer disposed under the first titanium nitride layer. The lanthanum layer may have a thickness of up to 1 nm, and the first titanium nitride layer may have a thickness of up to 10 nm. In the event the MOSFET 330 is a PMOS transistor, the stack of gate metal layers 308 can additionally include a second titanium nitride layer positioned beneath the first titanium nitride layer and the lanthanum layer described above. In some other examples, the MOSFET 330, as a PMOS transistor, may also include an aluminum layer. Here, the aluminum layer may have a thickness of up to 1 nm, and the second and/or third titanium nitride layers may have a thickness of up to 10 nm.

Referring now to the capping layer 312 shown deposited on the stack of gate metal layers 308 in FIG. 3, the capping layer 312 is configured to control or adjust the eWF level of the transistor gate stack 335. The capping layer 312 used in the present disclosure is much thinner than a thick (e.g., 9 nm or greater) polysilicon layer that is typically implemented in traditional transistor gate stacks. In one example, the capping layer 312 can be made of polycrystalline silicon (polysilicon) or amorphous silicon, and can have a thickness of up to 3 nm. For example, the capping layer 312 of the present disclosure can have a thickness of up to 3 nm, such as between 0 nm and 3 nm, between 2 nm and 3 nm, up to 2 nm, between 1 nm and 2 nm, or between 0 nm and 1 nm. In another example, the capping layer 312 can be made of titanium silicon nitride and can have a thickness of up to 5 nm, such as between 3 nm and 5 nm, between 0 nm and 3 nm, between 2 nm and 3 nm, or between 0 nm and 2 nm. In some other examples, the capping layer 312 can be made of a combination of a titanium silicon nitride layer with a polysilicon layer or an amorphous silicon layer. Here, the polysilicon layer or the amorphous silicon layer can be disposed above or under the titanium silicon nitride layer. The titanium silicon nitride layer can have a thickness of up to 5 nm, and the polysilicon layer or amorphous silicon layer can have a thickness of up to 3 nm.

The tungsten silicide (WSix) layer 314 is directly deposited on the capping layer 312, and the tungsten layer 318 is deposited on the WSix layer 314 in a top portion of the gate stack 335. The WSix layer 314 may have a thickness of up to 5 nm, such as close to 3 nm. The tungsten layer 318 may have a thickness up to 20 nm, such as close to 14 nm.

As discussed above, the MOSFET 330 can be fabricated using a gate-first process. In such a gate-first process, the gate stack 335 of the MOSFET 330 can be defined early in the fabrication sequence. For example, after the depositions of the interfacial layer 304, the high-K dielectric layer 306, the stack of gate metal layers 308, the capping layer 312, the tungsten silicide layer 314, and the tungsten layer 318, an additional layer (e.g., silicon nitride, not shown), a patterning process and an etching process can be applied to form the gate structure. Thereafter, the spacers 316 can be formed on either or both sides of the gate stack 335 to isolate the gate stack 335 from the source and drain regions of the substrate 322 and to protect the gate edge during subsequent processes. This approach allows for tight control over the gate's dimensions and its alignment with the channel in the substrate 322. In this example, the spacers 316 can be made of silicon nitride, silicon oxide, or a combination thereof.

Compared to traditional MOSFET devices that include thick polysilicon layers and associated barrier metal layers (e.g., titanium layers and tungsten nitride (WNx) layers disposed above the thick polysilicon layer), the present disclosure omits such thick polysilicon layers and associated barrier metal layers in transistor gate stacks (e.g., in the gate stack 335 of FIG. 3). Therefore, the present disclosure reduces the gate overlap capacitance (Cₒᵥ) and the gate stack resistance of the MOSFET 330. In addition, the gate stack structure of the MOSFET 330 illustrated in FIG. 3 effectively reduces the gate stack height of the periphery stack 310 (e.g., by approximately 13 nm), thereby achieving a reduction, minimization, or elimination of a height gap between the periphery stack 310 and the memory array 320 of FIG. 3. More specifically, as shown in FIG. 3, the MOSFET 330 has a height similar to the height of the adjacent memory array 320.

Further, in some embodiments, the present disclosure adopts a thin capping layer (e.g., the capping layer 312) and disposes it above the stack of gate metal layers (e.g., the stack of gate metal layers 308). The thin capping layer is expected to control the MOSFET gate eWF level. For example, merely omitting the typical thick polysilicon layer and the associated metal barrier layers may shift a transistor gate metal eWF of a gate stack to an undesirable or unacceptable level, especially in gate stacks in which tungsten is placed directly on a titanium nitride layer of the gate metal layers in a gate stack of an NMOS transistor. Thus, the present disclosure can employ a thin capping layer directly above and in contact with the stack of metal layers and/or directly beneath a metal barrier layer (e.g., a tungsten silicide layer, such as the tungsten silicide layer 314 of FIG. 3). The thin capping layer is expected to adjust (e.g., reduce, drop, increase, raise, shift) the eWF level of transistor gate stack to a desirable or acceptable level.

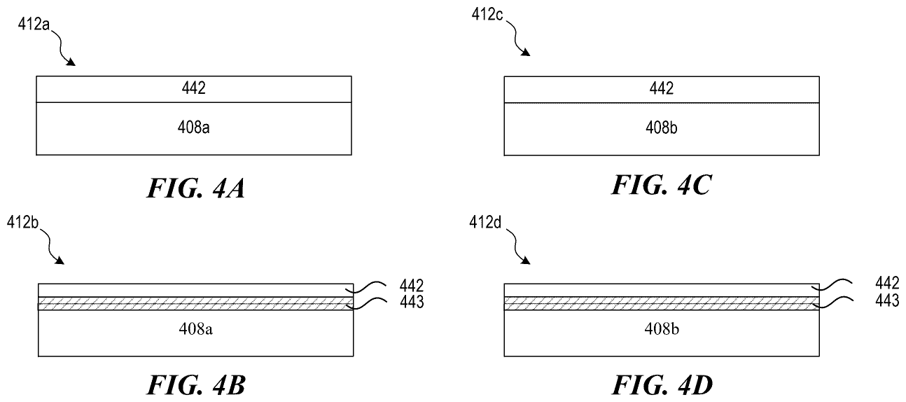

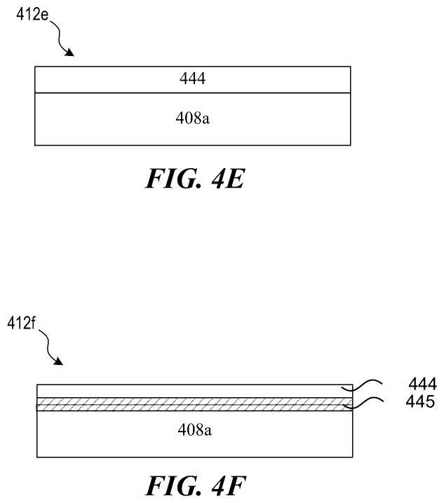

FIGS. 4A and 4B are partially schematic side views of capping layers 412a and 412b, respectively, configured in accordance with various embodiments of the present disclosure. The capping layers 412a and 412b can be examples of the capping layer 312 that is employed in the MOSFET 330 shown in FIG. 3. As shown in FIGS. 4A and 4B, the capping layers 412a and 412b are disposed or formed above a titanium nitride layer 408a of a stack of gate metal layers (e.g., the stack of gate metal layers 308 of FIG. 3).

Referring first to FIG. 4A, the capping layer 412a includes a silicon layer 442 deposited directly on a frontside surface of the titanium nitride layer 408a. For example, in some embodiments, the silicon layer 442 can be formed using a silane-based (SiH₄-based) thin film deposition process. In some other embodiments, the silicon layer 442 can be formed using other silicon containing source gases, such as disilane (Si₂H₆). In one example, a silane precursor can be introduced into a single wafer process tool (e.g., an atomic layer deposition tool) or a diffusion furnace tool as a reaction gas. The silane precursor can react when it arrives at or interacts with the frontside surface of the titanium nitride layer 408a, thereby forming the silicon layer 442. More specifically, catalytic formation of silicon can be conducted through a dehydrogenative coupling of silane at the surface of the titanium nitride layer 408a to form Si—Si bonds. Moreover, the silane can be introduced into a working chamber having a temperature close to 470° C. or higher such that it decomposes into silicon and hydrogen. Continuing with this example, the silane reaction gas may be (a) flown into the working chamber at a rate close to 500 sccm (or at another suitable flow rate) and/or (b) flown for approximately 15 minutes (or another suitable duration), onto the titanium nitride layer 408a at a temperature close to 475° C. Depending on a desired thickness of the silicon layer 442, the silane gas soak time can range from approximately 8 minutes to approximately 22 minutes, with longer durations expected to form a thicker silicon layer 442.

In another example, depositing the silicon layer 442 can additionally include an ammonia (NH₃) gas soak. For example, an ammonia gas can be flown into the vacuum chamber before and/or while introducing the above-described silane gas into the vacuum chamber, such as to assist with the silicon layer 442 deposition. In one example, an ammonia gas can be flown at a rate of 10 standard liters per minute (or at another suitable flow rate) into the working chamber for about 10 minutes (or another suitable duration). Here, the ammonia soak is expected to reduce the risk of the titanium nitride layer 408a oxidizing prior to the titanium nitride layer 408a interacting with the silane gas to form the silicon layer 442.

Other thin film deposition technologies can also be adopted to form the silicon layer 442. For example, a multiple wafer furnace tool can be used to introduce silane (e.g., at a similar or relatively lower process temperature) and grow the silicon layer 442 in the transistor gate stack. A total processing time of depositing the silicon layer 442 in the furnace tool may be over 2 hours and/or at approximately 475° C.

In some embodiments, the silicon layer 442 (e.g., formed using one or more of the above processes) can be a continuous, thin silicon layer having a thickness of up to 3 nm (e.g., between 0.5 nm and 2.5 nm, or between 1 nm and 2 nm). Depending on the silane gas flow rate and reaction temperature levels, the silicon layer 442 can be amorphous or poly crystalline. Here, the silicon layer 442 can serve as the capping layer 412a of a transistor gate stack and can shift (e.g., decrease) the eWF level of an NMOS gate to a desirable or acceptable level (e.g., a level identical or at least generally similar to a level of the NMOS gate when a thick polysilicon layer is employed).

Referring now to FIG. 4B, in comparison to the capping layer 412a of FIG. 4A, the capping layer 412b of FIG. 4B is disposed over a titanium silicide layer 443 that can be formed between (a) the silicon layer 442 of the capping layer 412b and (b) the titanium nitride layer 408a in the transistor gate stack. For example, a silane precursor can be introduced to form the titanium silicide layer 443 directly on the titanium nitride layer 408a and to form the silicon layer 442 over the titanium silicide layer 443. In this example, to form the titanium silicide layer 443, the reaction gas flow of the silane and reaction temperature can be adjusted to be slightly higher than that described in FIG. 4A. The titanium silicide layer 443 can include TiSi₂, TiSi, and/or a titanium-rich sub-silicide (e.g., Ti₅Si₄ and/or Ti₅Si₃). The adoption of a titanium silicide layer 443 between the silicon layer 442 and the titanium nitride layer 408a is expected to adjust gate resistance, such as by lowering its resistivity compared to polysilicon.

FIGS. 4C and 4D are partially schematic side views of capping layers 412c and 412d, respectively, configured in accordance with various embodiments of the present disclosure. Similar to the capping layers 412a and 412b described above with reference to FIGS. 4A and 4B, respectively, the capping layers 412c and 412d of FIGS. 4C and 4D, respectively, include a silicon layer 442. In contrast to the capping layers 412a and 412b, the capping layers 412c and 412d are deposited on a titanium silicon nitride layer 408b of a stack of gate metal layers (e.g., the stack of gate metal layers 308 of FIG. 3) rather than a titanium nitride layer (e.g., the titanium nitride layer 408a of FIGS. 4A and 4B). For example, the titanium silicon nitride layer 408b can be disposed in the upper region of the stack of gate metal layers, and a disilane (Si₂H₆) precursor (e.g., as opposed to a silane precursor) can be used as a reaction gas to form the silicon layer 442 of the capping layers 412c and 412d. A thin film deposition tool used in these examples can be similar to that described in FIGS. 4A and 4B. Here, however, a lower deposition temperature (e.g., 400° C.) can be configured to deposit the silicon layer 442 because disilane is chemically more active than silane and has a lower decomposing temperature. To achieve a similar silicon layer thickness as the silicon layer 442 of FIGS. 4A and 4B, a longer period of flowing disilane reaction gas (e.g., 30 minutes) may be employed to form the silicon layer 442 of the capping layers 412c and 412d. As shown in FIG. 4D, a titanium silicide layer 443 can be formed between silicon layer 442 and the titanium silicon nitride layer 408b. In this example, the formation of the titanium silicide layer 443 and its thickness can be controlled by adjusting the reaction gas flow of the disilane and reaction temperature. In these examples, the titanium silicon nitride layer 408b initiates the catalytic reaction of the disilane reaction gas and the deposition of the silicon layer 442 and/or the titanium silicide layer 443 thereon.

A capping layer of the present disclosure can additionally, or alternatively, be made of or include titanium silicon nitride. FIG. 4E is a partially schematic side view of a capping layer 412e that includes titanium silicon nitride layer 444 deposited on a frontside surface of a titanium nitride layer 408a of a stack of gate metal layers (e.g., the stack of gate metal layers 308 of FIG. 3). In these and other embodiments, a single wafer process tool (e.g., an atomic layer deposition tool), a diffusion furnace tool, or a PVD tool can be used to process the capping layer 412e. As a specific example, a gaseous source of titanium, a gaseous source of silicon, and/or a gaseous source of nitrogen can be flown into a reaction chamber and used to form the titanium silicon nitride layer 444 above the titanium nitride layer 408a. The chemical reaction temperature of the reaction chamber can be set at a temperature ranging from 100° C. to about 500° C. In this example, the silicon composition of the titanium silicon nitride layer 444 may range between 10% and 50%. Specifically, the flow rate of the gaseous source of titanium, the gaseous source of silicon, and/or the gaseous source of nitrogen can be adjusted as necessary or desired to form a titanium silicon nitride layer 444 having approximately 25% silicon. Here, the titanium silicon nitride layer 444 may have a thickness of up to approximately 5 nm. For example, the titanium silicon nitride layer 444 may have a thickness between 0 nm and 3 nm, between 0 nm and 2 nm, between 2 nm and 5 nm, between 1 nm and 2.5 nm, or between 1.5 nm and 3.5 nm. As a specific example, it is expected that the capping layer 412e (when including a titanium silicon nitride layer 444 of about 25% silicon and having a thickness of 3 nm) can maintain a similar eWF level of an NMOS gate and/or can increase the eWF level of a PMOS gate by about 80 meV, in comparison with a traditional transistor gate that employs a thick polysilicon layer. Moreover, the capping layer 412e can be associated with a thickness-reduced titanium nitride metal gate layer. For example, when employing a 3 nm titanium silicon nitride layer 444 in the capping layer 412e, the thickness of the titanium nitride layer 408a can be reduced (e.g., from about 5 nm to about 3 nm) so that a large gate stack height reduction can be achieved.

FIG. 4F is a partially schematic side view of a capping layer 412f configured in accordance with various embodiments of the present disclosure. As shown, the capping layer 412f is generally similar to the capping layer 412e of FIG. 4E except that a titanium silicide layer 445 is disposed between (a) the titanium silicon nitride layer 444 of the capping layer 412f and (b) the titanium nitride layer 408a of the gate stack.

In some examples, the capping layers 412e and 412f shown in FIGS. 4E and 4F can each be made of a combination of the titanium silicon nitride layer 444 and a polysilicon layer or an amorphous silicon layer (not shown). Particularly, the polysilicon layer or the amorphous silicon layer can be disposed above or underneath the titanium silicon nitride layer 444.

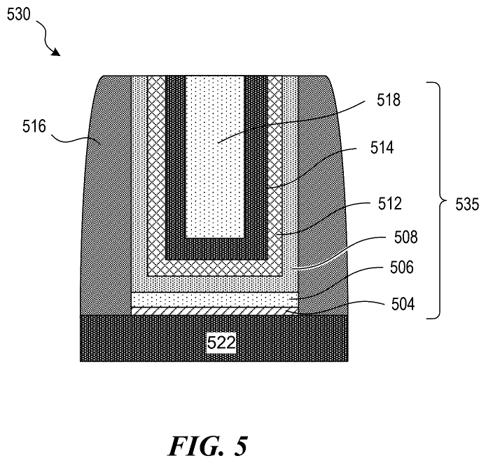

Although gate stacks of the present disclosure are described above as being formed at least partially using one or more gate-first fabrication processes, various gate stacks of the present disclosure may additionally, or alternatively, be formed using one or more gate-last fabrication processes (also known as replacement metal gate (RMG) processes). For example, FIG. 5 illustrates a partially schematic side view of a gate stack structure 535 (e.g., a high-k metal gate (HKMG) stack) of a MOSFET device 530 fabricated using a gate-last process and configured in accordance with various embodiments of the present disclosure. In this example, fabrication of the gate stack 535 can begin by depositing a layer of a sacrificial material (not shown), such as a thick polysilicon dummy layer, above the substrate 522 (with a gate dielectric layer disposed between polysilicon and the substrate 522). A photolithography process and an etching process can then be applied to pattern the sacrificial material to define dimensions of the gate stack 535 at a location over a channel region in the substrate 522. Dielectric spacers 516 can be formed on sidewall of the dummy gate structure. The dielectric spacers 516 can be made of materials similar to the spacer 316 described above with reference to FIG. 3. After the dielectric spacers 516 have been formed, additional source and drain regions engineering processes (e.g., doping and/or annealing processes) can be conducted to, for example, create heavily doped source and drain regions (not shown) in the substrate 522.

In a next step, the sacrificial dummy gate material can be selectively removed, leaving behind a space within which an interfacial layer 504, a high-K dielectric layer 506, and a stack of gate metal layers 508 can be deposited. As shown, the interfacial layer 504 and the high-K dielectric layer 506 can be sequentially deposited above the exposed frontside surface of the substrate 522. The stack of gate metal layers 508 can be conformally coated above the high-K dielectric layer 506 and on inner sidewalls of the dielectric spacers 516. Alternatively, the interfacial layer 504 and the high-K dielectric layer 506 can be formed before the sacrificial dummy gate deposition. Afterwards, a capping layer 512 can be conformally coated above a bottom portion and on sidewalls of the stack of gate metal layers 508. Here, the capping layer 512 can be made of polycrystalline silicon (polysilicon) or amorphous silicon, and/or can have a thickness of up to 3 nm (e.g., measured across a bottom portion of the capping layer 512 in a generally vertical direction in FIG. 5, and/or measured across a side portion of the capping layer 512 in a generally horizontal direction in FIG. 5). In another example, the capping layer 512 can be made of titanium silicon nitride and/or can have a thickness of up to 5 nm (e.g., measured across a bottom portion of the capping layer 512 in a generally vertical direction in FIG. 5, and/or measured across a side portion of the capping layer 512 in a generally horizontal direction in FIG. 5). In some other examples, the capping layer 512 can be made of a combination of a titanium silicon nitride layer with a polysilicon layer or an amorphous silicon layer. For example, the polysilicon layer or the amorphous silicon layer can be disposed above or under the titanium silicon nitride layer. The titanium silicon nitride layer can have a thickness of up to 5 nm, and the polysilicon layer or amorphous silicon layer can have a thickness of up to 3 nm.

In this example, the deposition process of forming the capping layer 512 can be similar to that described above with reference to FIGS. 4A-4F. As shown, the MOSFET device 530 further includes a tungsten silicide layer 514 deposited above the bottom region and on inner sidewalls of the capping layer 512. As shown in FIG. 5, a remaining space of the gate stack of the MOSFET device 530 can be filled by a tungsten layer 518. In this example, the tungsten silicide layer 514 may have a thickness of up to 5 nm (e.g., measured across a bottom portion of the tungsten silicide layer 514 in a generally vertical direction in FIG. 5, and/or measured across a side portion of the tungsten silicide layer 514 in a generally horizontal direction in FIG. 5). Additionally, or alternatively, the tungsten layer 518 can have a top surface that is coplanar with a top surface of the gate stack of the MOSFET device 530.

FIGS. 3-5 above describe gate stacks (a) that omit traditional thick polysilicon layers and associated barrier metals (e.g., titanium layers and/or tungsten nitride layers) from planar MOSFET devices and (b) that employ a capping layer (e.g., to achieve shorter gate stacks and/or to adjust gate stack eWF levels to desired or acceptable levels). The present disclosure is not, however, limited to planar MOSFET devices. For example, similar concepts can be implemented in advanced transistor structures, such as fin field-effect transistor (FinFET) devices, nanosheet gate all around (GAA) transistor devices, and nanowire GAA transistor devices.

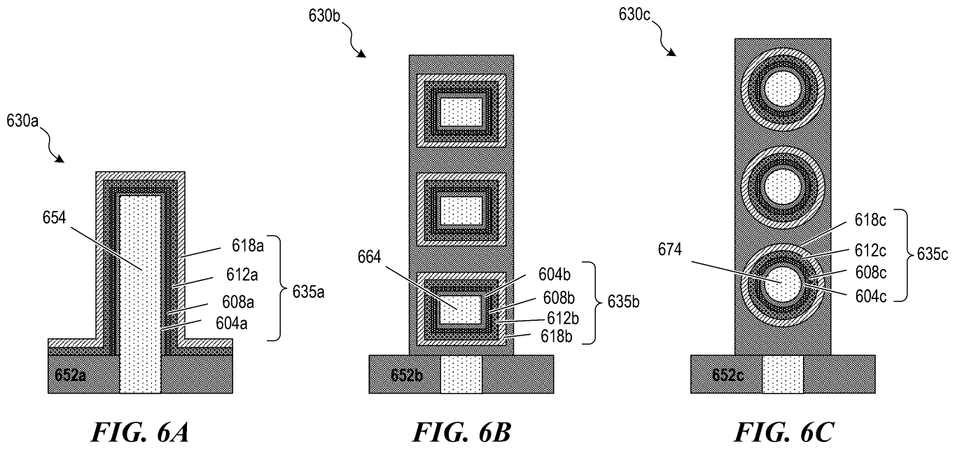

FIG. 6A is a partially schematic, cross-sectional side view of a FinFET device 630a configured in accordance with various embodiments of the present disclosure. In contrast with the planar field effect transistors (FETs) described above in which the gate stack is positioned on one side of a channel included in a corresponding substrate, the FinFET device 630a shown in FIG. 6A includes a narrow silicon structure 654 (also referred to herein as a fin 654) that extends at least partially through and/or rises above a substrate (not shown) of the FinFET device 630a to at least partially form a channel. As shown, a gate stack 635a (e.g., a high-k metal gate (HKMG) stack) of the FinFET device 630a includes a gate oxide layer 604a (e.g., including a high-K dielectric layer), a stack of gate metal layers 608a, a capping layer 612a, and another stack of gate metal layers 618a that each wraps around three sides (e.g., the top and both sidewalls) of the fin 654 to, for example, provide better control over the channel and/or reduce leakage current. In this example, the capping layer 612a (e.g., a polycrystalline silicon (polysilicon), an amorphous silicon layer, or a titanium silicon nitride layer) can be formed above the top and both sidewalls of the fin 654, and above the stack of gate metal layers 608a. Additionally, or alternatively, the capping layer 612a can have a similar thickness (e.g., measured across a top portion of the capping layer 612a in a generally vertical direction in FIG. 6A, and/or measured across one of the side portions of the capping layer 612a in a generally horizontal direction in FIG. 6A) to the capping layer 312 described above with reference to FIG. 3. In some embodiments, the gate metal layers 618a disposed over the capping layer 612a can include a tungsten silicide layer and/or a tungsten layer disposed above the tungsten silicide layer. In these and other embodiments, a shallow trench isolation (STI) dielectric layer 652a can be disposed next to the fin 654 to provide dielectric isolation. As shown, the capping layer 612a and gate metal layers 618a can at least partially extend laterally over a top of the STI dielectric layer 652a.

FIG. 6B is a partially schematic, cross-sectional side view of a nanosheet GAA transistor device 630b configured in accordance with various embodiments of the present disclosure. As shown, the nanosheet GAA transistor device 630b includes a plurality of vertically aligned nanosheets 664 and a corresponding plurality of gate stacks 635b (e.g., high-k metal gate (HKMG) stacks). Each of the nanosheets 664 functions as a channel and is surrounded by gate materials of a corresponding gate stack 635b that includes a gate oxide layer 604b (e.g., including a high-K dielectric layer), a stack of gate metal layers 608b, a capping layer 612b, and another stack of gate metal layers 618b, providing all-around control of the corresponding channel. For example, for a given one of the nanosheets 664, a corresponding capping layer 612b can completely surround a top surface, a bottom surface, and both side surfaces of the nanosheet 664. In this example, the capping layer 612b can have a similar thickness (e.g., measured across a bottom portion or a top portion of the capping layer 612b in a generally vertical direction in FIG. 6B, and/or measured across one of the side portions of the capping layer 612b in a generally horizontal direction in FIG. 6B) to the capping layer 312 described above with reference to FIG. 3. In addition, the gate metal layers 618b disposed about the capping layers 612b can include a tungsten silicide layer, and/or a tungsten layer disposed about the tungsten silicide layer. As shown in FIG. 6B, the stacked vertically aligned nanosheets 664 and corresponding gate stacks 635b can be disposed above an STI dielectric layer 652b.

FIG. 6C is a partially schematic, cross-sectional side view of a nanowire GAA transistor device 630c configured in accordance with various embodiments of the present disclosure. As shown, the nanowire GAA transistor device 630c includes a plurality of vertically aligned nanowires 674 and a corresponding plurality of gate stacks 635c (e.g., high-k metal gate (HKMG) stacks). Each of the nanowires 674 functions as a channel and is completely surrounded by gate materials of a corresponding gate stack 635c that includes a gate oxide layer 604c (e.g., including a high-K dielectric layer), a stack of gate metal layers 608c, a capping layer 612c, and another stack of gate metal layers 618c. In this example, the capping layer 612c can have a similar thickness (e.g., measured radially across a wall of the capping layer 612c) to the capping layer 312 described above with reference to FIG. 3. In some embodiments, the gate metal layers 618c disposed about the capping layer 612c can include a tungsten silicide layer, and/or a tungsten layer disposed about the tungsten silicide layer. As shown in FIG. 6B, the stacked vertically aligned nanowires 674 and corresponding gate stacks 635c can be disposed above an STI dielectric layer 652c.

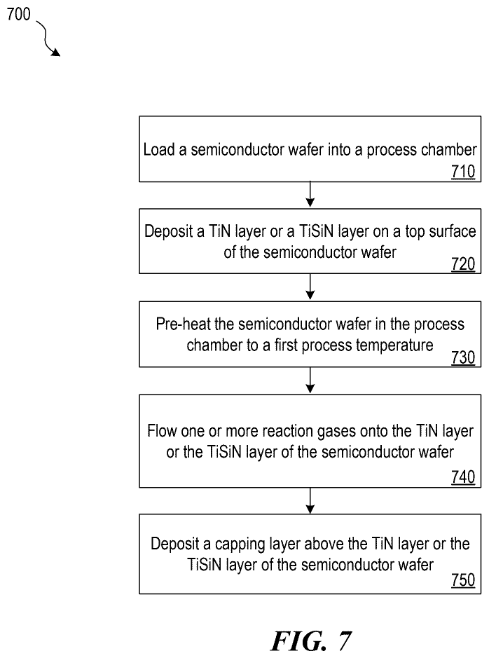

FIG. 7 is a flow chart illustrating a method 700 for fabricating at least part of a gate stack of a MOSFET device in accordance with various embodiments of the present disclosure. The method 700 begins at block 710 by loading a semiconductor wafer into a process chamber. For example, a semiconductor wafer containing a substrate (e.g., substrate 322 of FIG. 3) can be loaded into a vacuum chamber for metal stack material deposition. The vacuum chamber can be associated with a PECVD system, an atomic layer deposition (ALD) system, a chemical vapor deposition (CVD) system, or another suitable system.

At block 720, the method 700 continues by depositing a TiN layer (e.g., TiN layer 408a of FIGS. 4A, 4B, 4E, and/or 4F) or a TiSiN layer (e.g., TiSiN layer 408b of FIGS. 4C and/or 4D) on a top surface of the semiconductor wafer. For example, a stack of gate metal materials including a TiN layer or a TiSiN layer can be deposited (e.g., over an interfacial layer and/or a high-K dielectric layer) on a gate region of a MOSFET device. For example, the TiN layer or the TiSiN layer can be disposed in a top portion of such a stack of gate metal materials.

At block 730, the method 700 continues by pre-heating the semiconductor wafer in the process chamber to a first process temperature. For example, the semiconductor wafer containing the substrate 322 can be preheated to a temperature between approximately 400° C. and approximately 500° C.

At block 740, the method 700 continues by flowing one or more reaction gases onto or over the TiN layer or the TiSiN layer. For example, a silane reaction gas can be flown into the vacuum chamber (e.g., with a flow rate of approximately 500 sccm). The silane reaction gas can be delivered onto a frontside surface of the MOSFET for forming a titanium silicide layer (e.g., the titanium silicide layer 443 of FIG. 4B) above a titanium nitride layer (e.g., the titanium nitride layer 408a of FIG. 4B). In another example, a disilane reaction gas can be flown into the vacuum chamber (e.g., with a flow rate of approximately 500 sccm) for forming a titanium silicide layer (e.g., the titanium silicide layer 443 of FIG. 4D) over a titanium silicon nitride layer (e.g., the titanium silicon nitride layer 408b of FIG. 4D). In still another example, multiple reaction gases (e.g., a gaseous titanium, a gaseous silicon, and/or a gaseous nitrogen) can be flown into a reaction chamber, such as to form a titanium silicide layer (e.g., the titanium silicide layer 445 of FIG. 4F) above a titanium nitride layer (e.g., the titanium nitride layer 408a of FIG. 4F).

At block 750, the method 700 continues by depositing a silicon or a titanium silicon nitride layer above the TiN layer. For example, a silane reaction gas can be flown for approximately 15 minutes to grow a silicon layer (e.g., the silicon layer 442 of FIGS. 4A and/or 4B) having a thickness of up to 3 nm over a titanium nitride layer (e.g., the titanium nitride layer 408a of FIGS. 4A and/or 4B). In another example, a disilane reaction gas may be flown for approximately 30 minutes to grow a silicon layer (e.g., the silicon layer 442 of FIGS. 4C and/or 4D) having a thickness of up to 3 nm over a titanium silicon nitride layer (e.g., the titanium silicon nitride layer 408b of FIGS. 4C and/or 4D). In still another example, a gaseous titanium, a gaseous silicon, and/or a gaseous nitrogen can be flown for a certain amount of time to form a titanium silicon nitride layer (e.g., the titanium silicon nitride layer 444 of FIGS. 4E and/or 4F) having a thickness of up to 5 nm over a titanium nitride layer (e.g., the titanium nitride layer 408a of FIGS. 4E and/or 4F).

Although the blocks 710, 720, 730, 740, and 750 of the method 700 are discussed and illustrated in a particular order, the method 700 illustrated in FIG. 7 is not so limited. In other embodiments, the method 700 can be performed in a different order. In these and other embodiments, any of the blocks 710, 720, 730, 740, and 750 of the method 700 can be performed before, during, and/or after any of the other blocks 710, 720, 730, 740, and 750 of the method 700. Moreover, a person of ordinary skill in the relevant art will recognize that the illustrated method 700 can be altered and still remain within these and other embodiments of the present disclosure. For example, one or more blocks 710, 720, 730, 740, and 750 (e.g., block 740) of the method 700 illustrated in FIG. 7 can be omitted and/or repeated in some embodiments.

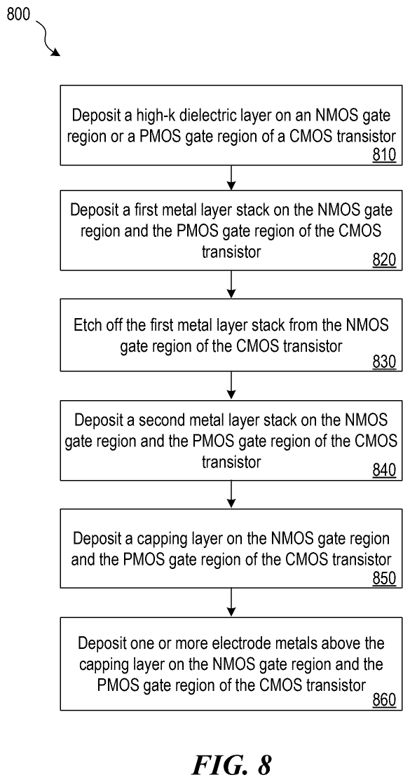

FIG. 8 is a flow chart illustrating a method 800 for fabricating a MOSFET device gate stack in accordance with various embodiments of the present disclosure. At block 810, the method 800 begins by depositing a high-K dielectric layer on an NMOS gate region or on a PMOS gate region of a transistor (e.g., a CMOS transistor). For example, the high-K dielectric layer 306 can be deposited above an interfacial layer and a channel formed in a substrate of the NMOS and PMOS transistors. In some embodiments, the high-K dielectric layer can be made of or include hafnium oxide.

At block 820, the method 800 continues by depositing a first metal layer stack on the NMOS gate region and on the PMOS gate region of the CMOS transistor. For example, the method 800 can include depositing a first stack of metal layers comprising a titanium nitride layer. In some embodiments, the first metal layer stack is disposed above the high-K dielectric layer.

At block 830, the method 800 continues by etching off the first metal layer stack from the NMOS gate region of the CMOS transistor. For example, the method 800 can include selectively removing the first stack of metal layers comprising the titanium nitride layer from the NMOS region of the CMOS transistor. In some embodiments, any PMOS gate regions of the CMOS transistor or of adjacent transistors can be covered by a hard mask layer, and the first metal layer stack can be etched off from the NMOS gate region of the CMOS transistor using a dry or wet etching process.

At block 840, the method 800 continues by depositing a second metal layer stack on the NMOS gate region and on the PMOS gate region of the CMOS transistor. For example, the method 800 can include depositing a second stack of metal layers comprising a lanthanum layer and a titanium nitride layer disposed above the lanthanum layer. The second metal layer stack can be directly deposited on the high-K dielectric layer 306 over the NMOS gate region and on the first metal layer stack over the PMOS gate region.

At block 850, the method 800 continues by depositing a capping layer on the NMOS gate region and on the PMOS gate region of the CMOS transistor. For example, the method 800 can include depositing or forming a thin silicon layer above the titanium nitride layer of the second metal layer stack in both of the PMOS and NMOS regions of the CMOS transistor. In another example, the method 800 can include depositing or forming a titanium silicon nitride layer as the capping layer above the metal layer stack in both of the PMOS and NMOS regions of the CMOS transistor.

At block 860, the method 800 continues by depositing one or more electrode metals above the capping layer on the NMOS gate region and on the PMOS gate region of the transistor. For example, the method 800 can include depositing a tungsten silicide layer and/or a tungsten layer over the capping layer. In this example, the method 800 can include employing a PECVD deposition process to deposit the tungsten silicide layer and/or the tungsten layer.

Although the blocks 810, 820, 830, 840, 850, and 860 of the method 800 are discussed and illustrated in a particular order, the method 800 illustrated in FIG. 8 is not so limited. In other embodiments, the method 800 can be performed in a different order. In these and other embodiments, any of the blocks 810, 820, 830, 840, 850, and 860 of the method 800 can be performed before, during, and/or after any of the other blocks 810, 820, 830, 840, 850, and 860 of the method 800. Moreover, a person of ordinary skill in the relevant art will recognize that the illustrated method 800 can be altered and still remain within these and other embodiments of the present disclosure. For example, one or more blocks 810, 820, 830, 840, 850, and 860 (e.g., block 830) of the method 800 illustrated in FIG. 8 can be omitted and/or repeated in some embodiments.

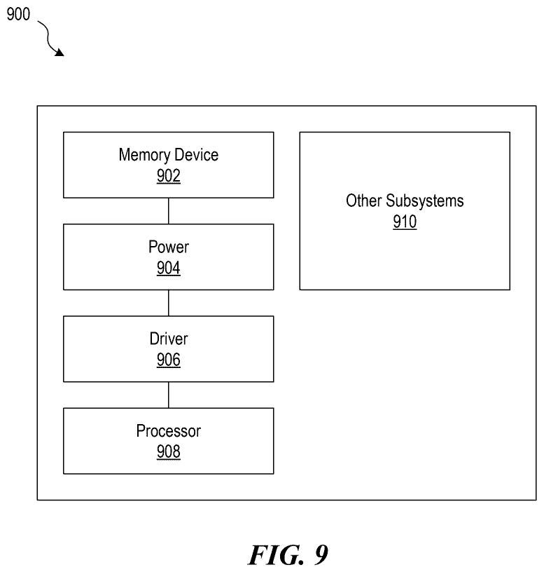

Any one of the semiconductor devices and semiconductor device assemblies described above with reference to FIGS. 2-8 can be incorporated into any of a myriad of larger and/or more complex systems, a representative example of which is system 900 shown schematically in FIG. 9. The system 900 can include a memory device 902 (or a discrete semiconductor device), a power source 904, a driver 906, a processor 908, and/or other subsystems or components 910. The memory device 902 can include features generally similar to those of the semiconductor devices described above with reference to FIGS. 2-8. The resulting system 900 can perform any of a wide variety of functions, such as memory storage, data processing, and/or other suitable functions. Accordingly, representative systems 900 can include, without limitation, hand-held devices (e.g., mobile phones, tablets, digital readers, and digital audio players), computers, vehicles, appliances and other products. Components of the system 900 may be housed in a single unit or distributed over multiple, interconnected units (e.g., through a communications network). The components of the system 900 can also include remote devices and any of a wide variety of computer readable media.

Specific details of several embodiments of semiconductor devices, and associated systems and methods, are described above. A person skilled in the relevant art will recognize that suitable stages of the methods described herein can be performed at the wafer level or at the die level. Therefore, depending upon the context in which it is used, the term “substrate” can refer to a wafer-level substrate or to a singulated, die-level substrate. Furthermore, unless the context indicates otherwise, structures disclosed herein can be formed using conventional semiconductor-manufacturing techniques. Materials can be deposited, for example, using chemical vapor deposition, physical vapor deposition, atomic layer deposition, plating, electroless plating, spin coating, and/or other suitable techniques. Similarly, materials can be removed, for example, using plasma etching, wet etching, dry etching, chemical-mechanical planarization, or other suitable techniques.

The devices discussed herein, including a memory device, may be formed on a semiconductor substrate or die, such as silicon, germanium, silicon-germanium alloy, gallium arsenide, gallium nitride, etc. In some cases, the substrate is a semiconductor wafer. In other cases, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorous, boron, or arsenic. Doping may be performed during the initial formation or growth of the substrate, by ion-implantation, or by any other doping means.

The functions described herein may be implemented in hardware, software executed by a processor, firmware, or any combination thereof. Other examples and implementations are within the scope of the disclosure and appended claims. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, the terms “vertical,” “lateral,” “upper,” “lower,” “above,” and “below” can refer to relative directions or positions of features in the semiconductor devices in view of the orientation shown in the Figures. For example, “upper” or “uppermost” can refer to a feature positioned closer to the top of a page than another feature. These terms, however, should be construed broadly to include semiconductor devices having other orientations, such as inverted or inclined orientations where top/bottom, over/under, above/below, up/down, and left/right can be interchanged depending on the orientation.

It should be noted that the methods described above describe possible implementations, and that the operations and the steps may be rearranged or otherwise modified and that other implementations are possible. Furthermore, embodiments from two or more of the methods may be combined.

From the foregoing, it will be appreciated that specific embodiments of the invention have been described herein for purposes of illustration, but that various modifications may be made without deviating from the scope of the invention. Rather, in the foregoing description, numerous specific details are discussed to provide a thorough and enabling description for embodiments of the present disclosure. One skilled in the relevant art, however, will recognize that the disclosure can be practiced without one or more of the specific details. In other instances, well-known structures or operations often associated with memory systems and devices are not shown, or are not described in detail, to avoid obscuring other aspects of the technology. In general, it should be understood that various other devices, systems, and methods in addition to those specific embodiments disclosed herein may be within the scope of the present disclosure.

What is claimed is:

1. A high-k metal gate (HKMG) stack, comprising:
a high-K dielectric layer;
a stack of gate work function metal layers disposed over the high-K dielectric layer;
a capping layer disposed over the stack of the gate work function metal layers, the capping layer having a thickness of 5 nm or less; and
a tungsten silicide layer disposed over and directly connected to the capping layer.

2. The HKMG stack of claim 1, wherein the capping layer is directly connected to the stack of the gate work function metal layers.

3. The HKMG stack of claim 1, wherein the stack of the gate work function metal layers includes a titanium nitride layer.

4. The HKMG stack of claim 3, wherein the titanium nitride layer is directly connected to the capping layer.

5. The HKMG stack of claim 3, further comprising a titanium silicide layer positioned between the titanium nitride layer and the capping layer.

6. The HKMG stack of claim 1, wherein the stack of the gate work function metal layers includes a titanium silicon nitride layer.

7. The HKMG stack of claim 1, wherein the capping layer includes polycrystalline silicon or amorphous silicon.

8. The HKMG stack of claim 1, wherein the capping layer includes a titanium silicon nitride layer.

9. The HKMG stack of claim 8, wherein the capping layer further includes a polysilicon layer or an amorphous silicon layer.

10. The HKMG stack of claim 9, wherein the polysilicon layer or the amorphous silicon layer is disposed above or underneath the titanium silicon nitride layer.

11. The HKMG stack of claim 1, further comprising a tungsten layer disposed on the tungsten silicide layer.

12. The HKMG stack of claim 1, wherein the stack of the gate work function metal layers includes (i) a lanthanum layer and (ii) a titanium nitride layer disposed over the lanthanum layer for NMOS.

13. The HKMG stack of claim 12, wherein for PMOS HKMG stack:
the titanium nitride layer is a first titanium nitride layer;
the stack of the gate work function metal layers further includes a second titanium nitride layer; and
the lanthanum layer and the first titanium nitride layer are disposed over the second titanium nitride layer.

14. A memory device, comprising:
a substrate;
a peripheral circuit stack disposed on the substrate, the peripheral circuit stack having a first height and including one or more transistors, each of the one or more transistors including a high-k metal gate (HKMG) stack comprising:
a high-K dielectric layer,
a stack of gate work function metal layers disposed on the high-K dielectric layer,
a capping layer disposed on the stack of the gate work function metal layers, the capping layer having a thickness of 5 nm or less, and
a tungsten silicide layer disposed over and directly connected to the capping layer; and
a memory array disposed on the substrate and connected to the peripheral circuit stack, the memory array having a second height similar to the first height of the peripheral circuit stack.

15. A semiconductor device, comprising:
a substrate including a channel region formed therein; and
a gate stack disposed on the substrate and configured to control the channel region, the gate stack including:
a dielectric layer disposed on the substrate,
a stack of gate work function metal layers disposed on the dielectric layer,
a capping layer disposed on the stack of the gate work function metal layers, the capping layer having a thickness of 5 nm or less, and
a tungsten silicide layer disposed over and directly connected to the capping layer.

16. The semiconductor device of claim 15, wherein:
the semiconductor device is a planar metal-oxide-semiconductor field-effect transistor (MOSFET); and
the dielectric layer, the stack of the gate work function metal layers, and the capping layer are disposed above a top surface of the channel region.

17. The semiconductor device of claim 15, wherein:
the semiconductor device is a fin field-effect transistor (FinFET);
the dielectric layer is disposed (a) over a top surface of the channel region and (b) over side surfaces of the channel region;
the stack of the gate work function metal layers are disposed (a) over the top surface of the channel region and (b) adjacent to the side surfaces of the channel region; and
the capping layer is disposed (a) over the top surface of the channel region and (b) adjacent to the side surfaces of the channel region.

18. The semiconductor device of claim 15, wherein:
the semiconductor device is a nanosheet field-effect transistor;
the channel region comprises a plurality of horizontally stacked nanosheets;
the dielectric layer wraps around each of the plurality of horizontally stacked nanosheets;
the stack of the gate work function metal layers wraps around each of the plurality of horizontally stacked nanosheets; and
the capping layer wraps around each of the plurality of horizontally stacked nanosheets.

19. The semiconductor device of claim 15, wherein:
the semiconductor device is a nanowire field-effect transistor;
the channel region comprises a plurality of horizontally stacked nanowires;
the dielectric layer wraps around each of the plurality of horizontally stacked nanowires;
the stack of the gate work function metal layers wraps around each of the plurality of horizontally stacked nanowires; and
the capping layer wraps around each of the plurality of horizontally stacked nanowires.
